(19) United States
(12) Patent Application Publication
(10) Pub. No.: US 2024/0026517 A1
(43) Pub. Date: Jan. 25, 2024

(54) MASK-SUPPORT ASSEMBLY AND PRODUCING METHOD THEREOF

(71) Applicant: Olum Material Corporation, Yongin-si (KR)

(72) Inventors: Taek Yong JANG, Seongnam-si (KR); Young Ho LEE, Yongin-si (KR); Hwi Su KIM, Yongin-si (KR); Dong Jin LEE, Osan-si (KR); Byung Il LEE, Seongnam-si (KR)

(73) Assignee: Olum Material Corporation, Yongin-si (KR)

(21) Appl. No.: 18/135,937

(22) Filed: Apr. 18, 2023

(30) Foreign Application Priority Data
Jul. 22, 2022 (KR) 10-2022-0091157
Aug. 4, 2022 (KR) 10-2022-0097125
Aug. 5, 2022 (KR) 10-2022-0097839
Sep. 22, 2022 (KR) 10-2022-0120077
Nov. 29, 2022 (KR) 10-2022-0163155
Jan. 31, 2023 (KR) 10-2023-0012920

(51) Int. Cl. C23C 14/04; H10K 99/00; C25D 1/10; C23C 14/12

(52) U.S. Cl. CPC C23C 14/042; H10K 99/00; C25D 1/10; C23C 14/12; H10K 71/166

(57) ABSTRACT

A mask-support assembly and a producing method thereof are provided. The mask-support assembly, which is used in a process of forming organic light-emitting diode (OLED) pixels on a semiconductor wafer, includes: a support comprising an edge portion and a grid portion; and a mask connected onto the support and comprising a plurality of cell portions in each of which a mask pattern is formed.

### CROSS-REFERENCE TO RELATED APPLICATION(S)

This application claims the benefit under 35 USC § 119(a) of Korean Patent Application No. 10-2022-0091157 filed on Jul. 22, 2022, No. 10-2022-0097125 filed on Aug. 4, 2022, No. 10-2022-0097839 filed on Aug. 5, 2022, No. 10-2022-0120077 filed on Sep. 22, 2022, No. 10-2022-0163155 filed on Nov. 29, 2022 and No. 10-2023-0012920 filed on Jan. 31, 2023 in the Korean Intellectual Property Office, the entire disclosure of each of which is herein incorporated by reference for all purposes.

### BACKGROUND

### 1. Field

The following description relates to a mask-support assembly and a producing method thereof. More specifically, the following description relates to a mask-support assembly that is used in forming pixels on a semiconductor wafer and enables a mask pattern of ultra-high resolution to be precisely formed, and a producing method thereof.

### 2. Description of Related Art

As a pixel deposition technique in an organic light-emitting diode (OLED) manufacturing process, a fine metal mask (FMM) scheme for positioning a thin metal mask (or a shadow mask) in contact with or very close to a substrate and depositing an organic material at desired locations is commonly used.

In a conventional OLED manufacturing process, after a mask thin film is prepared, a mask is welded and fixed to an OLED pixel deposition frame and then is used. In the fixing process, there is a problem in that the mask of a large area is not well aligned. Also, in the process of welding and fixing the mask to the frame, there is a problem in that the mask sags or twists with the load since the mask film is too thin and has a large area.

In an ultra-high-resolution OLED manufacturing process, small defects of several μm may lead to pixel deposition failure, and thus there is a need to develop technology that is capable of preventing deformation of a mask, such as sagging or twisting of a mask, and clearly aligning the mask.

Recently, a microdisplay which is applied to a virtual reality (VR) device has drawn attention. A microdisplay is required to provide a much smaller screen size than those of the existing displays and still realize high quality within the small screen in order to display an image directly in front of a user's eye in a VR device. Therefore, smaller mask patterns than those of a mask used in the existing ultra-high-resolution OLED manufacturing process and a finer alignment of the mask before a pixel deposition process are required.

### SUMMARY

Therefore, the present invention is devised to solve the above-mentioned problems of the related art and provides a mask-support assembly capable of realizing ultra-high definition pixels of a microdisplay, and a producing method thereof.

Moreover, the present invention provides a mask-support assembly capable of enhancing stability of pixel deposition by allowing a mask to be clearly aligned, and a producing method thereof.

However, these objects are merely illustrative, and the scope of the present invention is not limited thereto.

The present invention provides a mask-support assembly which is used in a process of forming organic light-emitting diode (OLED) pixels on a semiconductor wafer, the mask-support assembly including a support including an edge portion and a grid portion; and a mask connected onto the support and including a plurality of cell portions in each of which a mask pattern is formed.

A thickness of the grid portion may be thinner than that of the edge portion.

The support and the mask may have a circular shape, and the grid portion may include a plurality of first grid portions extending in a first direction and having both ends connected to the edge portion; and a plurality of second grid portions extending in a second direction different from the first direction to intersect with the first grid portions and having both ends connected to the edge portion.

The mask may include a dummy portion connected onto the edge portion; a plurality of cell portions disposed at a central part of the mask and including a plurality of mask patterns; and separation portions positioned closer to the central part of the mask than the dummy portion and disposed between the plurality of cell portions, and the separation portions may be supported on the grid portion.

The support may be formed from a silicon wafer, and the mask may be formed on the silicon wafer by electroforming.

A connection potion including Ni and Si or a connection portion including Fe, Ni, and Si may be interposed between the support and the mask.

A connection portion including at least one of Ni, Cu, Au, Ag, Al, Sn, In, Bi, Zn, Sb, Ge, or Cd may be interposed between the support and the mask.

The mask may be made of at least one of Invar, Super Invar, nickel (Ni), cobalt (Co), titanium (Ti), chromium (Cr), tungsten (W), or molybdenum (Mo).

The mask may include a first mask layer and a second layer formed of a material different from that of the first mask layer, the first mask layer may be made of a material including at least one of Ni, Cu, Au, Ag, Al, Co, Ti, Cr, W, or Mo, the second mask layer may be made of Invar or Super Invar, and the first mask layer may mediate a connection between the support and the mask.

A crystal orientation of a (100) plane or (111) plane of the silicon wafer may not be parallel to a longitudinal direction of the first grid portions or the second grid portions.

The mask may include a dummy portion connected on the edge part; the plurality of cell portions positioned closer to a central part of the mask than the dummy portion and including a plurality of mask patterns and slit lines may be formed between each cell portion so that the cell portions may be spaced apart from each other.

The edge portion and the grid portion may include tapered sides.

A surface resistance of the support may be 5×10⁻⁴ ohm cm to 1×10⁻⁴ ohm cm.

The dummy portion may include a plurality of dummy cell portions that include a plurality of dummy patterns formed to pass through the dummy portion or formed to a predetermined depth on the dummy portion.

Also, the present invention provides a producing method of a mask-support assembly which is used in a process of forming OLED pixels on a semiconductor wafer, the producing method including the steps of: (a) preparing a support which includes a first surface and a second surface opposite to the first surface and is a conductive substrate; (b) forming a mask on the first surface by electroforming; (c) performing heat treatment on the support and the mask; and (d) forming an edge portion and a grid portion by etching the support on the second surface of the support.

The producing method may further include, between steps (a) and (b), (a2) forming a connection portion including at least one of Ni, Cu, Au, Ag, Al, Sn, In, Bi, Zn, Sb, Ge, or Cd, and in step (b), the mask may be formed on the connection portion by electroplating.

After the heat treatment in step (c), the mask and the support may be connected to each other by interposing a connection portion including Ni and Si or a connection portion including Fe, Ni, and Si.

The heat treatment in step (c) may be performed at a temperature of 200° C. to 800° C.

The producing method may further include, between steps (c) and (d), (c2) reducing a thickness of at least a region where the grid portion is to be formed on the second surface of the support portion.

Moreover, the present invention may provide a mask-support assembly which is used in a process of forming OLED pixels on a semiconductor wafer, the mask-support assembly including: a support which includes: an edge portion; a plurality of first grid portions extending in a first direction and having both ends connected to the edge portion; and a plurality of second grid portions extending in a second direction different from the first direction to intersect with the first grid portions and having both ends connected to the edge portion, and has a circular shape; a mask which is connected onto the support, includes a plurality of cell portions in each of which a mask pattern is formed, and has a circular shape; and a connection portion configured to mediate a connection between the support and the mask, wherein the support is formed from a silicon wafer, the mask is formed on the silicon wafer by electroforming, the connection portion includes any one of the following (1) to (3): (1) Ni and Si; (2) Fe, Ni, and Si; and (3) at least one of Ni, Cu, Au, Ag, Al, Sn, In, Bi, Zn, Sb, Ge, or Cd, and the mask is made of at least one of Invar, Super Invar, nickel (Ni), cobalt (Co), titanium (Ti), chromium (Cr), tungsten (W), or molybdenum (Mo).

Other features and aspects will be apparent from the following detailed description, the drawings, and the claims.

### BRIEF DESCRIPTION OF THE DRAWINGS

FIG. 1 is a schematic diagram illustrating a mask-support assembly according to an embodiment of the present invention.

FIG. 2 is a schematic cross-sectional view taken along line A-A′ of FIG. 1.

FIGS. 3A-3B illustrate a schematic plan view and a schematic cross-sectional view taken along line E-E′ showing a mask according to an embodiment of the present invention.

FIG. 4 is a schematic plan view showing a support according to an embodiment of the present invention.

FIGS. 5 to 11 are schematic diagrams illustrating a producing process of a mask-support assembly according to a first embodiment of the present invention.

FIGS. 12A-12C illustrate a schematic plan view and schematic cross-sectional views taken along, respectively, lines E-E′ and F-F′ showing a mask according to another embodiment of the present invention.

FIG. 13 is a schematic plan view showing a support according to another embodiment of the present invention.

FIGS. 14 to 21 are schematic diagrams illustrating a producing process of a mask-support assembly according to a second embodiment of the present invention.

FIG. 22 is a schematic diagram illustrating a mask-support assembly according to another embodiment of the present invention.

FIGS. 23A-23B illustrate a schematic plan view and a schematic side cross-sectional view taken along line G-G′ showing a mask on which slit lines are formed according to an embodiment of the present invention.

FIG. 24 is a schematic diagram showing an organic light emitting diode (OLED) pixel deposition apparatus to which a mask-support assembly according to one embodiment of the present invention is applied.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed descriptions of the invention will be made with reference to the accompanying drawings illustrating specific embodiments of the invention by way of example. These embodiments will be described in detail such that the invention can be carried out by one of ordinary skill in the art. It should be understood that various embodiments of the invention are different, but are not necessarily mutually exclusive. For example, a specific shape, structure, and characteristic of an embodiment described herein may be implemented in another embodiment without departing from the scope of the invention. In addition, it should be understood that a position or placement of each component in each disclosed embodiment may be changed without departing from the scope of the invention. Accordingly, there is no intent to limit the invention to the following detailed descriptions. The scope of the invention is defined by the appended claims and encompasses all equivalents that fall within the scope of the appended claims. In the drawings, like reference numerals denote like functions, and the dimensions such as lengths, areas, and thicknesses of elements may be exaggerated for clarity.

Hereinafter, to allow one of ordinary skill in the art to easily carry out the invention, embodiments of the present invention will be described in detail with reference to the accompanying drawings.

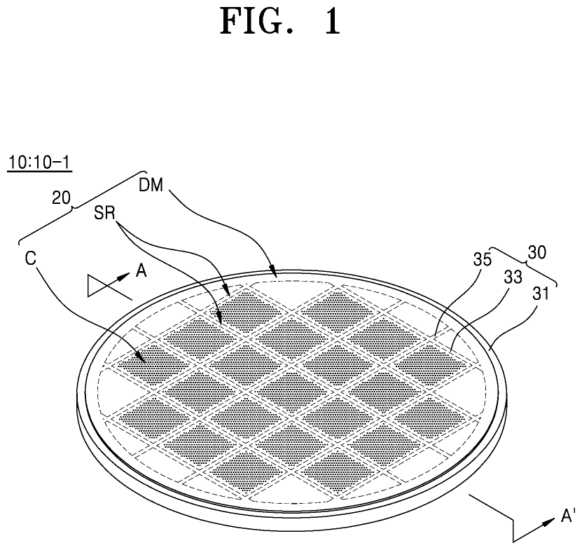

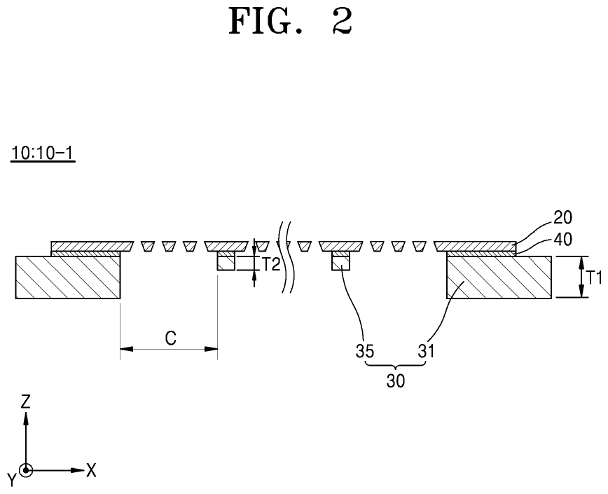

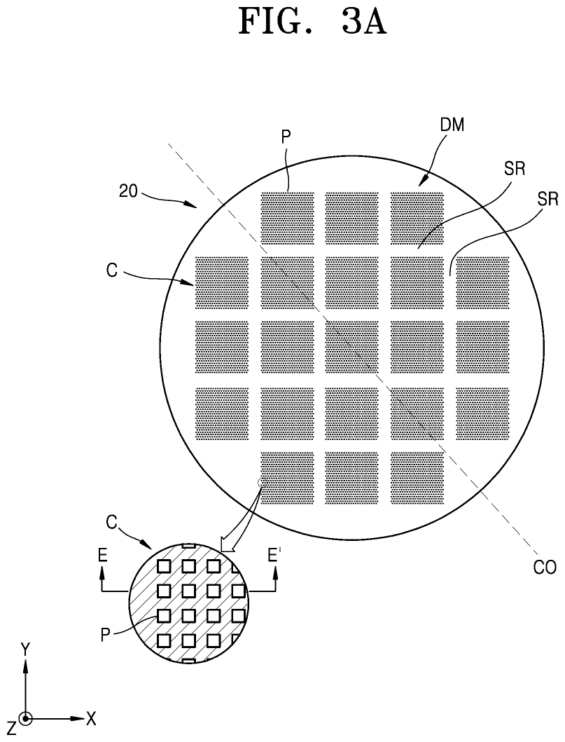

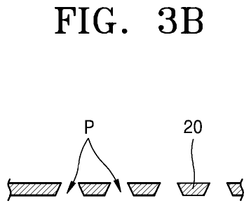

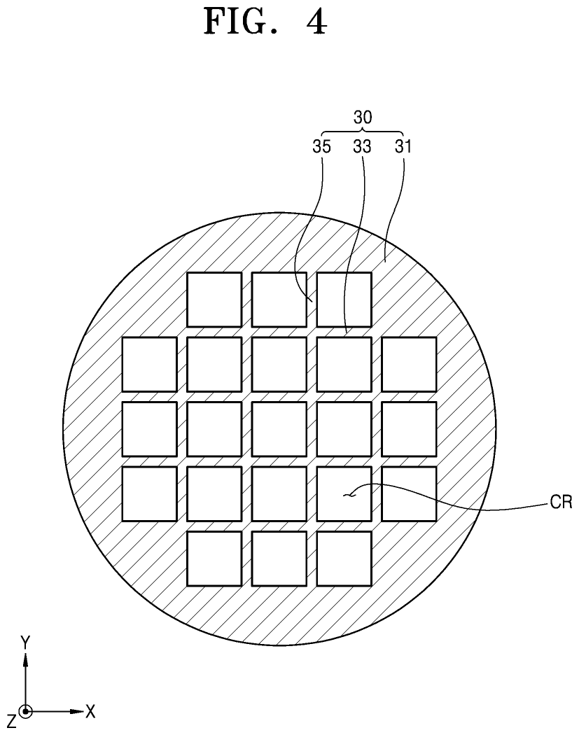

FIG. 1 is a schematic diagram illustrating a mask-support assembly 10 according to an embodiment of the present invention. FIG. 2 is a schematic cross-sectional view taken along line A-A′ of FIG. 1. FIGS. 3A-3B illustrate a schematic plan view and a schematic cross-sectional view taken along line E-E′ showing a mask 20 according to an embodiment of the present invention. FIG. 4 is a schematic plan view showing a support 30 according to an embodiment of the present invention.

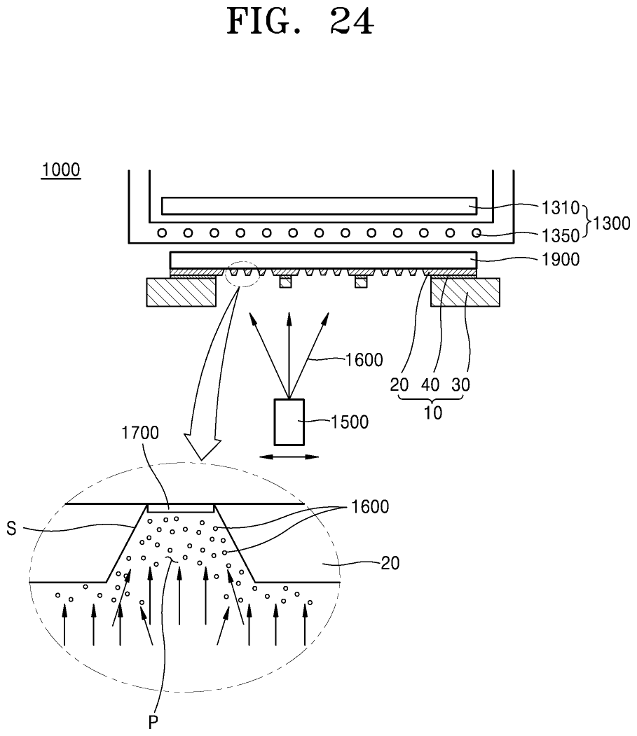

A microdisplay, which is recently applied to a virtual reality (VR) device, may be used in a pixel deposition process for a target substrate 1900 (see FIG. 24), such as a silicon wafer or a silicon wafer, rather than for a substrate of a large area. The microdisplay has a screen that is about 1 to 2 inches smaller than the size of the large area substrate because a screen is positioned directly in front of an eye of a user. Moreover, implementation of higher resolution is required since the screen is positioned closely in front of the eye of the user. Moreover, implementation of higher resolution is required since the screen is positioned closely in front of the eye of the user.

Accordingly, the present invention is directed to provide a mask-support assembly 10 which, rather than being used in a pixel formation process for a target substrate of a large area with a side length exceeding 1,000 mm, allows for a pixel formation process on the target substrate 1900 (e.g., a semiconductor silicon target wafer) of 200 mm, 300 mm, or 450 mm such that ultra-high-resolution pixels are formed, and a producing method thereof.

For example, currently, quad high definition (QHD) image quality is 500 to 600 pixels per inch (PPI), and a size of each pixel is about 30 to 50 μm, and a 4K ultra-high definition (UHD) or 8K UHD image quality has a resolution of up to 860 PPI or up to 1600 PPI, which is higher than the QHD image quality. A microdisplay directly applied to a VR device or a microdisplay inserted into a VR device is aimed at realizing ultra-high resolution of approximately 2000 PPI or higher and has a pixel size of about 5 to 10 μm. In the case of a semiconductor wafer or a silicon waver, a finer and more precise process is possible compared to a glass substrate by utilizing technologies developed in a semiconductor process, and hence the semiconductor wafer or silicon wafer may be employed as a substrate of a high-resolution microdisplay. The present invention is characterized by a mask-support assembly 10 that allows for formation of pixels on the silicon wafer.

Referring to FIGS. 1 and 2, the present invention is characterized in that a mask 20 has a shape corresponding to a semiconductor wafer (or a silicon wafer) in order to perform a pixel deposition process on the semiconductor wafer as a target substrate 1900 (see FIG. 24). When the shape of the mask 20 corresponds to the semiconductor wafer, it means that the mask 20 has the same shape and size as those of the semiconductor wafer or that the mask 20 has a different size and shape from the semiconductor wafer but is coaxial to the semiconductor wafer while mask patterns P are disposed within the shape of the semiconductor wafer. In addition, the mask 20 that has a shape corresponding to the semiconductor wafer is characterized in that it is integrally connected to the support 30 and is thereby clearly aligned.

The mask-support assembly 10 may include the mask 20 and the support 30. The mask 20 may be connected onto one surface of the support 30. The support 30 may serve as a frame that supports the mask 20.

Referring to FIGS. 1 to 3, the mask 20 may include cell portions C, separation portions SR, and a dummy portion DM. Each cell portion C is a portion of the mask 20 that is not in contact with the support 30 and where the mask patterns P are formed, each separation portion SR is a portion disposed between the cell portions C, and the dummy portion DM is a portion attached to the support 30. Although the cell portion C, the separation portion SR, and the circular dummy portion DM may be denoted by different names and reference characters according to the formed positions thereof, the cell portion C, the separation portion SR, and the dummy portion DM are not separated regions and are configured to be integrally formed with the same material. In other words, the cell portion C, the separation portion SR, and the circular dummy portion DM are each part of the mask 20, which are simultaneously formed in an electroforming process. Hereinafter, the cell portion C, the separation portion SR, and the dummy portion DM may be used interchangeably with the mask 20.

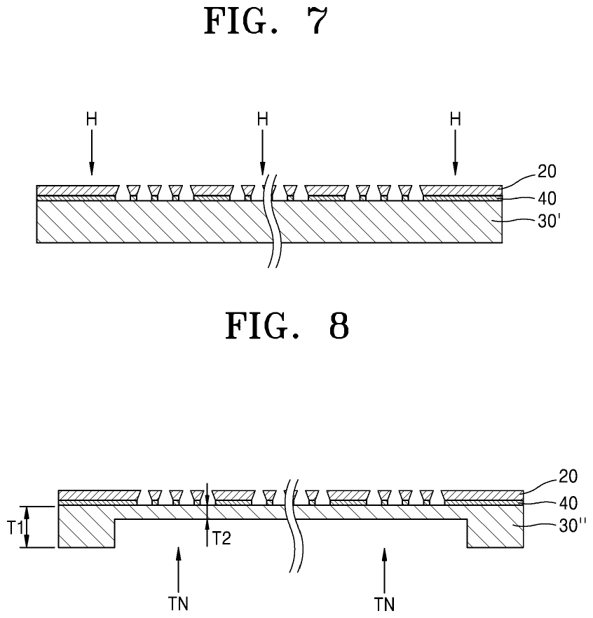

The mask 20 is made of an Invar or Super Invar material. Alternatively, the mask 20 may include a metal material that can be electroformed with nickel (Ni), cobalt (Co), titanium (Ti), chromium (Cr), tungsten (W), molybdenum (Mo), or a combination or alloy thereof and is capable of forming silicide with a silicon component of the support 30′ (or a conductive substrate 30′, see FIG. 7). Alternatively, the mask 20 may include a Super Invar material containing a tertiary or higher Co. The mask 20 may have a circular shape to correspond to the circular semiconductor wafer. The mask 20 may have a size corresponding to a silicon wafer of 200 mm, 300 mm, 450 mm, or the like.

A conventional mask has a shape of rectangle, polygon, or the like to correspond to a substrate of a large area. In addition, a frame also has a shape of rectangle, polygon, or the like to correspond to the mask. Since the mask has angled corners, there may be a problem in that stress is concentrated on the corners. Concentration of stress may cause different forces to act on only a portion of the mask, which may twist or distort the mask, leading to a failure of pixel alignment. In particular, at an ultra-high resolution of 2000 PPI or higher, stress concentration on the corners of the mask should be avoided.

Thus, as the mask 20 of the present invention has a circular shape, the mask 20 does not s have any corners. That is, the dummy portion DM of the mask 20 may have a circular shape and have no corners. Since there is no corner, it is possible to solve the problem that different force acts on a specific portion of the mask 20, and the stress may be uniformly distributed along a circular edge. Accordingly, the mask 20 may contribute to clear pixel alignment without being twisted or distorted, and mask patterns P of 2000 PPI or higher may be realized. The present io invention performs a pixel deposition process by matching a circular semiconductor wafer (or a circular silicon wafer) having a low coefficient of thermal expansion and the circular mask 20 in which the stress is uniformly distributed along the edge, so that pixels with a size of approximately 5 to 10 μm may be deposited.

A plurality of mask patterns P may be formed in the cell portion C. The mask patterns P may be a plurality of plurality pixel patterns P that correspond to red (R), green (G), and blue (B) pixels. Sides of each mask pattern P may have a sloped shape, a tapered shape, or a shape in which a pattern width gradually increases from the upper portion toward the lower portion. A number of mask patterns P may be grouped to form a single display cell portion C. The display cell portion C may have a diagonal length of approximately 1 to 2 inches, and may be a portion that corresponds to one microdisplay. Alternatively, the display cell portion C may be a portion that corresponds to a plurality of displays.

The mask pattern P may have a substantially tapered shape, and may have a pattern width of several to several tens of μm, or of approximately 5 to 10 μm (resolution of 2000 PPI or higher).

The mask 20 may include a plurality of cell portions C. The plurality of cell portions C may be arranged at predetermined intervals in a first direction (x-axis direction) and in a second direction (y-axis direction) that is perpendicular to the first direction. In FIG. 1, it is shown that 21 cell portions C are arranged along the first and second directions, but the present invention is not limited thereto. The separation portion SR may be disposed between the cell portions C. The cell portion C and the separation portion SR are portions that are positioned closer to the central part of the mask 20 than the dummy portion DM.

The dummy portion DM may define the outer shape of the mask 20 with a circular edge or a shape corresponding to a semiconductor wafer. The dummy portion DM may be connected onto the support 30. Specifically, the dummy portion DM may be attached and connected to at least a portion of an edge portion 31 of the support 30. The dummy portion DM and the edge portion 31 may be attached to each other via a connection portion 40 formed therebetween.

Referring to FIGS. 1, 2, and 4, the support 30 may include the edge portion 31, a plurality of first grid portions 33, and a plurality of second portions 35. Although the edge portion 31 and the first and second grid portions 33 and 35 may be denoted by different names and reference characters, the edge portion 31 and the first and second grid portions 33 and 35 are not separated regions and are configured to be integrally formed with the same material. Hereinafter, the edge portion 31 and the first and second grid portions 33 and 35 may be used interchangeably with the support 30.

The support 30 is made of a silicon material. In some embodiments, the support 30 may be formed from a silicon wafer and made of a monocrystalline silicon material. The edge portion 31 of the support 30 may have a circular shape such that the support 30 corresponds to a circular semiconductor wafer that is a target substrate 1999 (see FIG. 24). The support 30 may have a shape of the same size or at least larger than the mask 20 so that the mask 20 can be connected to an upper portion of the support 30.

The edge portion 31 may define the outer shape of the support 30. The edge portion 31 may have a circular shape. However, the edge portion 31 may have a different shape as long as electroforming of the mask 20 can be easily performed and the support 30 corresponds to a semiconductor wafer, enabling an OLED pixel process.

The plurality of first grid portions 33 may extend in the first direction and may each have both ends connected to the edge portion 31. In addition, the plurality of second grid portions 35 may extend in a second direction that is different from the first direction to intersect with the first grid portions 33, and may each have both ends connected to the edge portion 31. For example, the first direction may be an x-axis direction, and the second direction may be a y-axis direction and be perpendicular to the first direction. The first grid portions 33 may be arranged in parallel to each other at predetermined intervals, and the second grid portions 35 may be arranged in parallel to each other at predetermined intervals. Also, since the first and second grid portions 33 and 35 intersect with each other, empty regions CR, in the form of a matrix, may appear at the intersecting portions. These empty regions CR where the cell portions C of the mask 20 are disposed are referred to as “cell regions CR” (see FIG. 4).

The thickness of the support 30 may be greater than the thickness of the mask 20. In order to realize mask patterns P of 2000 PPI or higher, the thickness of the mask 20 may be approximately 2 μm to 12 μm. If the mask 20 is thicker than the aforementioned thickness, it may be difficult to form the mask patterns P, having an overall tapered shape, to have the width or spacing that meets the desired resolution.

Of the support 30, the thickness T1 of the edge portion 31 may be greater than the thickness T2 of the first grid portion 33 and/or the second grid portion 35.

The edge portion 31 may serve as a frame in the mask-support assembly 10, have rigidity to support the mask 20, and may have the thickness T1 that is thicker than the first and second grid portions 33 and 35 in order to prevent the support 30 from deforming or warping as a whole. For example, the thickness T1 of the edge portion 31 may be approximately 700 μm to 1,000 μm when a silicon wafer is directly applied, and approximately 500 μm to 1,000 μm when a predetermined thickness reduction is applied.

In an embodiment, the thickness T2 of the first and second grid portions 33 and 35 is greater than the thickness of the mask 20 and thinner than the edge portion 31 because the first and second grid portions 33 and 35 should be provided with the cell regions CR (see FIG. 4) therebetween, through which an organic material source 1600 passes, while supporting at least the mask 20 and the organic material source 1600 should not cause shadow effect due to the thickness T2 of the first and second grid portions 33 and 35. For example, the thickness T2 of the first and second grid portions 33 and 35 may be approximately 50 μm to 200 μm.

According to another embodiment, the thickness T1 of the edge portion 31 and the thickness T2 of the first and/or second grid portions 33 and 35 may be equal to each other. In this case, the edge portion 31 may also have a thickness of approximately 50 μm to 200 μm by applying a thickness reduction to a silicon wafer.

The connection portion 40 may be interposed between the mask 20 and the support 30. The mask 20 may be connected onto the support 30 with the connection portion 40 interposed between them. The edge portion 31 of the support 30 may be connected to the dummy portion DM of the mask 20, and the first and second grid portions 33 and 35 of the support 30 may be connected to the separation portions SR of the mask 20. That is, the separation portions SR may be supported on the first and second grid portions 33 and 35.

According to one embodiment, the connection portion 40 may be formed by thermal treatment H (see FIG. 7) in a state of a laminate in which the mask 20 is formed onto the support 30. In this case, the connection portion 40 may be provided as an intermetallic compound in which the component of the mask 20 and the component of the support 30 are combined. The connection portion 40 may contain Ni and Si, or Fe, Ni, and Si, as Fe and Ni component of the mask 20 and Si component of the support 30 are combined, or may be provided as a silicide containing Fe and Ni. By the bond strength of the intermetallic compound, the mask 20 and the support 30 may be connected to each other with the connection portion 40 interposed therebetween.

In addition, according to one embodiment, the connection portion 40 may serve as an adhesion layer that mediates adhesion such that the mask 20 is formed with a higher adhesive strength on the support 30. For example, in the case where the support 30 is a silicon wafer, the adhesive strength of the mask 20 is higher when the mask 20, which is made of Invar, Super Invar, or the like, is adhered to the support 30 through the connection portion 40 made of Ni, Cu, or the like, than when the mask 20 is directly adhered to the support 30. Taking this into account, the connection portion 40 may contain at least one of Ni, Cu, Au, Ag, Al, Sn, In, Bi, Zn, Sb, Ge, or Cd.

As the support 30 also has a circular edge like the mask 20 and has no corners, it is possible to solve the problem that different force acts on a specific portion of the support 30. In addition, the stress may be uniformly distributed along the circular edge. Accordingly, this may contribute to preventing the support 30 from being twisted or distorted. Since the circular mask 20 is connected to the circular support 30, there is an effect of dually distributing the stress. Furthermore, as the first and second grid portions 33 and 35 of the support 30 are disposed below the separation portions SR of the mask 20 and support the mask 20 entirely, the ultra-thin mask 20 may be prevented from sagging at the cell portions C and the separation portions SR. As a result, the mask 20 and the support 30 may contribute to clear pixel alignment without being distorted, and a resolution of 2000 PPI or higher may be realized.

Referring back to FIG. 3A, a crystal orientation (CO) of the (100) or (111) plane of the silicon wafer may not be parallel to the longitudinal directions of the first and second grid portions 33 and 35. The first and second grid portions 33 and 35 may extend along the x-axis direction or the y-axis direction, and the crystal orientation CO of the (100) or (101) plane of the silicon wafer of the support 30 may not be parallel to the x-/y-axis direction (at an angle of 0° or 180°) and may have a predetermined angle other than 0° or 180° with respect to the x-/y-axis direction. In another aspect, the crystal orientation CO of the (100) or (111) plane of the silicon wafer may have a predetermined angle, which is not 0° or 180°, with respect to the x-/y-axis direction in which the plurality of cell portions C are disposed. The silicon wafer is more likely to be broken in the crystal orientation CO of the (100) or (111) plane than in other crystal orientations. As the cell portions C, the separation portions SR, and the like of the mask 20 that correspond to the first and second grid portions 33 and 35 are arranged in a staggered manner in the crystal orientation CO, the risk of breakage of the mask-support assembly 10 is reduced and overall rigidity is increased.

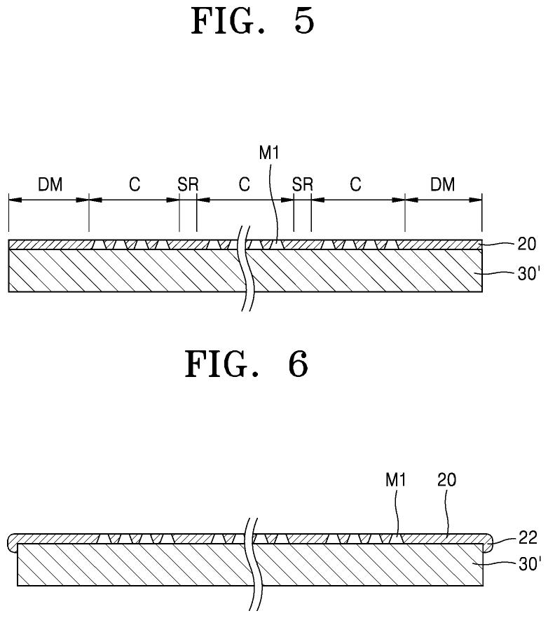

FIGS. 5 to 11 are schematic diagrams illustrating a producing process of a mask-support assembly 10-1 (or 10) according to a first embodiment of the present invention.

Referring to FIG. 5, a support 30′ is prepared. The support 30′ may be a conductive substrate 30′ made of a conductive material to perform electroforming. To achieve conductivity and have low resistance, the support 30′ (or the conductive substrate 30′) may be highly doped at a concentration higher than or equal to 1019 cm-3. The doping may be performed on the entire support 30′ or on only the surface of the support 30′. According to one embodiment, the surface resistance of the support 30′ may be 5×10⁻⁴ to 1×10⁻² ohm·cm. The support 30′ may be used as a cathode in electroforming.

Unlike metals having metal oxide on the surface thereof and polycrystalline silicon having a grain boundary, doped monocrystalline silicon does not have defects, and thus a uniform plated film (or a mask 20) may be formed due to generation of a uniform electric field on a whole surface in an electroforming process. The mask 20 prepared through the uniform plated film may increase the resolution of OLED pixels. Moreover, since a process for removing or preventing defects is not additionally required, process costs may be reduced and productivity may be increased.

Then, a patterned insulating portion M1 may be formed on one surface of the support 30′. The insulating portion M1 is a part formed to protrude (embossed) from one surface of the support 30 ′, and may have insulation properties to prevent the formation of the plated film (or the mask 20). Accordingly, the insulating portion M1 may be made of at least one of a photoresist material, a silicon oxide material, or a silicon nitride material. The insulating portion M1 may be formed by forming a silicon oxide or a silicon nitride on the support 30′ using deposition or the like, and thermal oxidation or thermal nitridation may be used using the support 30′ as a base. A photoresist may be formed using a printing method or the like. The insulating portion M1 may be thicker than the plated film to be formed.

The insulating portion M1 may have a tapered shape. When patterns in a tapered shape are formed using a photoresist, a multiple exposure method, a method of varying an exposure intensity per region, or the like may be used.

Then, the mask 20 may be formed by performing electroforming on the support 30′. The support 30′ is used as a cathode body and an anode body (not shown) facing the support 30′ is prepared. The anode body may be dipped in a plating solution (not shown), and the entire or a part of the support 30′ may be dipped in the plating solution. Since the insulating portion M1 has the insulating properties, a plated film is not formed on a portion that corresponds to the insulating portion M1, so that mask patterns P of the mask 20 may be formed. The mask patterns P (or the insulating portion M1) may be formed on a region that corresponds to the cell portion C.

Meanwhile, the composition of the mask 20 may be controlled so that the mask 20 has a coefficient of thermal expansion (CTE) similar to that of a silicon material of the support 30′. In the mask-support assembly 10, the support 30 serves as a frame made of silicon, and the mask 20 should have a similar coefficient of thermal expansion to that of the support 30 so that the mask 20 does not sag on the support 30, which is a frame. In addition, the change in pixel position accuracy (PPA), which is misalignment of the cell portions C and the mask patterns P on the support 30, may be reduced.

Taking this into account, the composition of the mask 20 may be controlled so that the coefficient of thermal expansion of the support 30′ made of silicon and the coefficient of thermal expansion of the mask 20 after heat treatment H which will be described below become approximately (3.5±1)X10⁻⁶ / C. Even if the mask 20 is made of Invar, the coefficient of thermal expansion of the mask 20 may be controlled to be as same as possible to the coefficient of thermal expansion of the support 30 made of silicon by performing electroforming by varying the composition ratio of Fe and Ni. Alternatively, the coefficient of thermal expansion of the mask 20 may be controlled to be smaller or greater than that of the support 30 so that the mask 20 can be tightly connected onto the support 30 according to process temperature conditions.

Referring to FIG. 6, electroforming may be performed so that the mask 20 is formed on the upper surface and the side surface of the support 30′, rather than being formed only on the upper surface of the support 30′. In the case of performing heat treatment H which will be described below, if the mask 20 is formed only on the upper surface of the support 30′, there is a risk that the edge portion of the mask 20 will be peeled off during the heat treatment H process, and thus a plated film 22 may also be formed further on the side surface of the support 30′. Accordingly, as the plated film 22 on the side surface reinforces the adhesion to the support 30′ on the side surface of the support 30′, the entire mask 20 may not be peeled off during the heat treatment H process, and may be well fixed and adhered to the support 30′. The plated film 22 on the side surface may be removed later by etching or laser cutting.

Also, in the case of performing heat treatment H which will be described below, the mask 20 formed by electroforming needs to be well adhered to the support 30′ without peeling off. To this end, other methods may be considered in addition to plaiting on the upper and side surfaces shown in FIG. 6.

As one of methods, a native oxide of the support 30′ on which electroforming is performed may be controlled. An oxide may be formed on the surface of the support 30′ made of a silicon wafer. On the surface with such an oxide, a uniform electric field is not generated, and hence the plated film (the mask 20) may not be uniformly produced, and the adhesion between the produced plated film (the mask 20) and the support 30′ may be low. Therefore, a process of removing native oxide is followed by an electroforming process.

As another method, another film may be further formed to mediate adhesion between the plated film (the mask 20) and the support 30′. In addition to a barrier film, which will be described below, a film or a combination of films providing adhesion to both surfaces of the film may be used.

Alternatively, the surface of the support 30′ may be pre-treated before electroforming. Through physical treatment or chemical treatment, the plated film (the mask 20) produced in the electroforming process may be formed to have stronger adhesion on the support 30′. In addition, by controlling the plating method in the electroforming process, the plated film (the mask 20) may be formed to have stronger adhesion on the support 30′.

Then, referring to FIG. 7, heat treatment H may be performed on the mask 20 and the support 30′. The heat treatment may be performed at a temperature of 300° C. to 800° C.

Generally, an Invar thin plate produced by electroforming has a higher coefficient of thermal expansion as compared to an Invar thin plate produced by rolling. Thus, by performing heat treatment on the Invar thin plate, the coefficient of thermal expansion can be lowered. In this heat treatment, slight deformation may occur in the Invar thin plate. If heat treatment is performed only on the mask 20 that exists separately, slight deformation may occur in the mask patterns P. Hence, when heat treatment is performed in a state where the support 30′ and the mask 20 are adhered to each other, the shape of the mask pattern P formed in a space portion occupied by the insulating portion M1 of the support 30′ may be advantageously prevented from minute deformation due to the heat treatment.

In addition, the coefficient of thermal expansion of the invar thin plate produced by electroforming and the coefficient of thermal expansion of the silicon wafer are approximately 3 to 4 ppi, which are almost the same as each other. Thus, even when the heat treatment H is performed, since the degree of thermal expansion of the mask 20 and the degree of thermal expansion of the support 30′ are the same, there is no misalignment due to thermal expansion and the minute deformation of the mask pattern P can be prevented.

Additionally, the present invention is characterized in that the mask 20 and the support 30′ are connected to each other by the heat treatment H. During the heat treatment H process, a connection portion 40 may be formed between the mask 20 and the support 30′. The connection portion 40 may be provided as an intermetallic compound in which the component of the mask 20 and the component of the support 30′ are combined. The connection portion 40 may contain Ni and Si, or Fe, Ni, and Si, as Fe and Ni component of the mask 20 and Si component of the support 30 are combined, or may be provided as a silicide containing Fe and Ni. By the bond strength of the intermetallic compound, the mask 20 and the support 30′ may be attached to each other with the connection portion 40 interposed therebetween.

According to one embodiment, the following electroforming pre-treatment/electroforming conditions are required as formation conditions of the connection portion 40 provided as a silicide. First, the mask 20 may be electroformed on the support 30′ that has been highly doped at a concentration higher than or equal to 10¹⁹ cm⁻³ and has a surface resistance of approximately 5×10⁻⁴ to 1×10⁻² ohm·cm. Second, prior to the electroforming of the mask 20, the surface of the support 30′ made of a silicon wafer material may be subjected to HF treatment to form a Si surface in which SiO is controlled. Third, Ni-silicide may be promoted by forming Ni-rich Fe-Ni at the beginning and controlling the composition so that Ni content is 35 to 45%. Alternatively, prior to the electroforming of the mask 20 having Fe-Ni components, a first mask layer made of Ni, Co, Ti, etc. may be added as a glue layer to promote the formation of silicide.

Also, according to one embodiment, the heat treatment H may be performed at a temperature of 300° C. to 800° C., and may proceed in a number of steps. As 2-step heat treatment, is after forming Ni₂Si at a low temperature range (approximately 250 to 350° C. to adhere the mask 20 onto the support 30′, heat treatment may be carried out by gradually raising the temperature to a high temperature range (approximately 450 to 650° C.). In the case of an Invar mask produced by electroforming, since it has a microcrystal and/or amorphous structure, when temperature is rapidly raised during the heat treatment, the Invar mask may be detached or separated from the support 30′ due to volume shrinkage. Therefore, in an embodiment, heat treatment may be performed by gradually raising the temperature to high temperature after adhering the Invar mask to the silicon wafer support 30′ at low temperature.

In addition, according to one embodiment, a reducing atmosphere should be maintained during the heat treatment H. The reducing atmosphere may be formed as H₂, Ar, or N₂ atmosphere, and may use a dry N₂ gas to prevent oxidation of the Invar mask. In order to prevent oxidation of the Invar mask, it is necessary to manage the O₂ concentration to be less than 100 ppm. Alternatively, a vacuum atmosphere of <10⁻² torr may be formed. The heat treatment H may be performed for 30 minutes to 2 hours.

As the connection portion 40 (adhesive layer) such as Ni silicide, (Ni, Fe)Si silicide, or the like is formed at the interface of the mask 20 electroformed on the silicon wafer support 30′, the mask 20 and the support 30′ may be connected to each other with the connection portion 40 interposed therebetween.

Meanwhile, to control the reaction of Ni and Fe-Ni with Si during the heat treatment H, a barrier film (not shown) may be formed on the support 30′ prior to the electroforming of the mask 20 on the support 30′. The barrier film may prevent the components (e.g., Ni and Fe-Ni) of the plated film of the mask 20 from permeating uncontrollably into the silicon support 30′. At the same time, the barrier film has conductivity so that electroforming can be performed on the surface. Taking this into account, the barrier film may include a material, such as titanium nitride (TiN), titanium/titanium nitride (Ti/TiN), tungsten carbide (WC), titanium tungsten (WTi), graphene, or the like. A thin film formation process such as deposition of barrier film may be used without limitations. The barrier film may control the reaction of Fe and Ni with Si so that uniform silicide can be formed and the mask 20 and the connection portion 40 can be attached to each other with appropriate adherence strength. In addition, the barrier film may be configured as a film or a combination of films capable of providing predetermined adhesion or adherence so that the mask 20 is not separated from the support 30′ in a state in which the mask 20 is electroformed on the support 30′.

The support 30′ and the mask 20 may be connected by adjusting the temperature and time to control the thickness of the connection portion 40 (silicide thickness) to 10 to 300 nm.

Then, referring to FIG. 8, a thickness reduction process TN of the support 30′ (or the conductive substrate 30′) may be performed. The thickness reduction process TN may be performed on a lower surface (second surface) that is opposite to the upper surface (first surface) of the support 30′ in contact with the mask 20. The thickness reduction process TN may be s performed using lapping, polishing, buffing, etc.

The thickness reduction process TN may be performed on a central part of the support 30′. The thickness reduction process TN may be performed on a region of the support 30′ that corresponds to a region where the cell portions C of the mask 20 are disposed. Alternatively, the thickness reduction process TN may be performed on a region where the first and second grid portions 33 and 35 are to be formed, and may not be performed on a region where the edge portion 31 is to be formed. The region where the first and second grid portions 33 and 35 are to be formed may even include regions that correspond to at least a part of the cell portions C, the separation portions SR, and the dummy portion DM of the mask 20.

Accordingly, in the support 30′ subjected to the thickness reduction process TN, the thickness T2 of the grid portions 33 and 35 is smaller than the thickness T1 of the edge portion 31, and at least steps may be formed between the grid portions 33 and 35 and the edge portion 31.

On the other hand, the thickness reduction process TN may be divided into stages, wherein a primary thickness reduction process may be performed as a whole on the lower surface (second surface) of the support 30′ and then a secondary thickness reduction process may be performed on the region where the first and second grid portions 33 and 35 are to be formed.

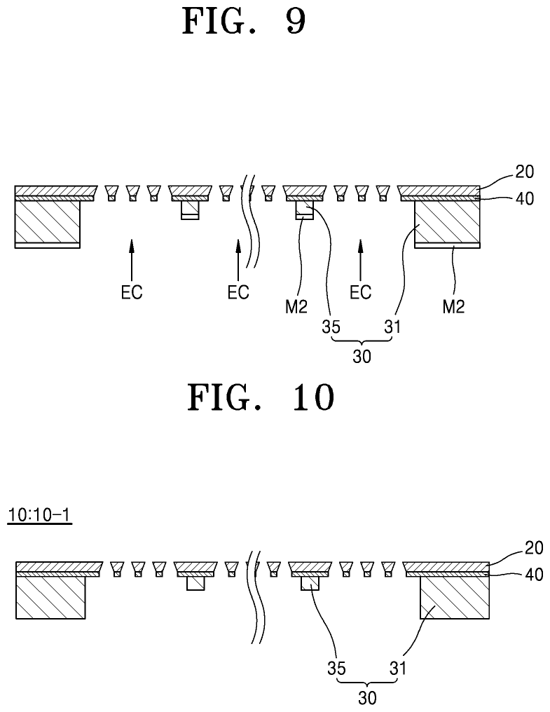

Optionally, the thickness reduction process TN may not be performed on the region where the first and second grid portions 33 and 35 are to be formed as long as the shadow effect does not occur. In this case, the process of FIG. 7 may directly proceed to the process which will be described with reference to FIG. 9.

Then, referring to FIG. 9, the support 30′ may be subjected to etching EC. The etching EC may be performed on the second surface (lower surface) that is opposite to the first surface (upper surface) of the support 30′ connected to the mask 20. A region of the support 30′ that corresponds to the cell portion C of the mask 20 may be subjected to etching EC. A region that corresponds to the separation portion SR of the mask 20 is not subjected to etching.

The support 30 which has been subjected to etching EC may have a shape including the edge portion 31 and the first and second grid portions 33 and 35. The etching EC may use a dry etching method having anisotropic etching characteristics so that the edge portion 31 and the first and second grid portions 33 and 35 clearly appear in the support 30. Since the support 30′ is a silicon wafer, there is an advantage in that etching EC may be performed by utilizing existing semi conductor-related technologies and micro-electro mechanical system-related technologies.

In order to impart etch resistance, an insulating portion M2 may be formed on the lower surface of the support 30′ except for a portion corresponding to the cell portion C. The insulating portion M2 may be formed of photoresist using a printing method or the like, and silicon oxide or silicon nitride serving as a hard mask may be formed by a method such as thermal oxidation or thermal nitridation. Meanwhile, a metal may be used as a mask for etching. A portion exposed on the lower surface of the support 30′ that is not covered by the insulation portion M2 may be etched EC.

Then, referring to FIG. 10, the mask-support assembly 10 may be produced by removing the insulating portion M2 and performing a subsequent process, such as cleaning or the like. A support 30 may include an edge portion 31 and first and second grid portions 33 and 35, and a mask 20 may be connected onto the support 30 by interposing a connection portion 40 between them. The cell portion C of the mask 20 may be provided as an area having an open lower part that is not supported by the support 30, so that it may be provided as a moving path of an organic material source (see FIG. 24) during an OLED pixel deposition process.

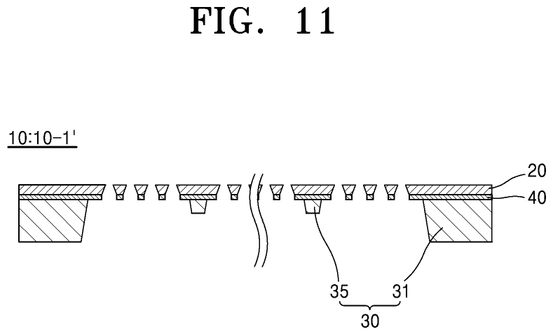

FIG. 11 is a schematic diagram illustrating a mask-support assembly 10-1′ (or 10) according to another embodiment of the present invention.

Wet etching, rather than dry etching, may be performed as the etching EC process of FIG. 9. Since wet etching has isotropic etching characteristics, undercut may occur in the insulating portion M2 on the second surface (lower surface) of the support 30′. Also, due to the isotropic etching characteristics, side surfaces of the edge portion 31 and the first and second grid portions 33 and 35 may be formed to be tapered as shown in FIG. 11. In this case, since the organic material io source 1600 can move at an inclined angle along the tapered side surface. Thus, shadow effect may be primarily prevented in the support 30 and then secondarily prevented in the tapered mask patterns P.

As described above, a frame is formed by processing the support 30 in a state in which a separate physical tension is not applied to the mask 20 after forming the mask 20 on the support 30 through electroforming. Thus, there is no risk of misalignment of the mask. Accordingly, the mask is clearly aligned so that stability of pixel deposition can be improved and at the same time an ultra-high resolution of 2000 PPI or higher can be realized.

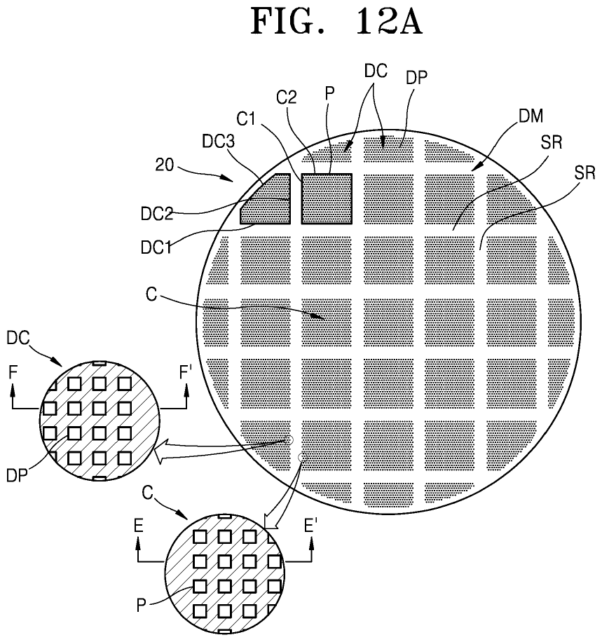

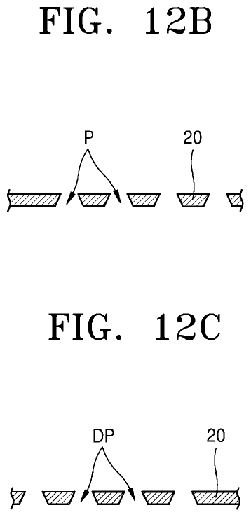

FIGS. 12A-12C illustrate a schematic plan view and schematic cross-sectional views taken along, respectively, lines E-E′ and F-F′ showing a mask 20 according to another embodiment of the present invention. FIG. 13 is a schematic plan view showing a support 30 according to another embodiment of the present invention.

Although the mask 20 of FIG. 3A has a circular edge, the cell portions C including the mask patterns P may have a rectangular shape. When the cell portions C are disposed at the substantially central part of the mask 20 along the first and second directions, the distance from each cell portion C to the edge of the circular mask 20 may be different. In another aspect, areas contacting each cell portion C and the dummy portion DM may be different. Accordingly, stress levels may be non-uniform in each region of the cell portion C and the dummy portion DM of the mask 20.

In addition, the cell portion C has mask patterns P formed to penetrate the mask 20, whereas the dummy portion DM has no penetrating patterns, and thus the dummy portion DM is less deformed by stress, and the cell portion C is inevitably more deformed even by the same stress. In the mask-support assembly 10, mask patterns P are finely formed and their positions should not be changed so that ultra-high-quality OLED pixels of 500 to 600 PPI or more, or of 2000 PPI or more can be configured. Accordingly, it is required to uniformly match the stress levels acting on the cell portions C and the dummy portion DM. This may be equally applied to the cell region CR and the dummy cell region DCR of the support 30.

Referring back to FIG. 12A, the dummy portion DM of the present invention may include a plurality of dummy cell portions DC. The plurality of dummy cell portions DC may be arranged at predetermined intervals in a first direction (x-axis direction) of the cell portion C and in a second direction (y-axis direction) that is perpendicular to the first direction. The predetermined interval between the dummy cell portion DC and the cell portion C may correspond to predetermined interval between the cell portions C. A separation portion SR may also be disposed between the dummy cell portion DC and the cell portion C.

A length of at least one side of the dummy cell portion DC may correspond to a length of one side of the cell portion C. The cell portion C may be provided in a quadrilateral shape, and edge sides C1 and C2 of the cell portion C may be formed as straight lines perpendicular to each other. When the cell portion C is of a square shape, C1 and C2 have the same length, and when the cell portion C is of a rectangular shape, C1 and C2 may have different lengths from each other. The dummy cell portion DC may be arranged on an extended line of the cell portion C along the first and second directions, but it may be difficult to provide the dummy cell portion DC in a quadrilateral shape due to the nature of being arranged at the edge of the mask 20. The dummy cell portion DC may have a shape in which at least some side has a curvature. In another aspect, two to four sides of the edge sides DC1, DC2, and DC3 of the dummy cell portion DC may be provided as straight lines, and some of the sides may be provided as curved lines. In FIG. 12A, for example, two sides DC1 and DC2 of the uppermost dummy cell portion DC are provided as straight lines and side DC3 is provided as two straight lines and one curved line. In another example, the rightmost/leftmost dummy cell portions DC and the uppermost/lowermost dummy cell portions DC may have a substantially angular “C” shape with three sides provided as straight lines, and the right side thereof is provided as a curved line.

In addition, a plurality of dummy patterns DP may be formed in the dummy cell portion DC. As shown in FIG. 12A, the dummy patterns DP may be formed to have the same shape as the mask patterns P. For example, sides of each dummy pattern P may have a sloped shape, a tapered shape, or a shape in which a pattern width gradually increases from the upper portion toward the lower portion. The plurality of dummy patterns DP may be grouped to form a single dummy cell portion DC. The dummy pattern DP may have a substantially tapered shape, and may have a pattern width of several to several tens of μm, or of approximately 5 to 10 μm (resolution of 2000 PPI or higher).

Meanwhile, the dummy patterns DP may be formed to a predetermined depth even if they penetrate the mask 20 in a thickness direction as long as they maintain uniformity of stress in the entire area of the mask 20. Also, the dummy patterns DP may not necessarily have the same shape and size as the mask patterns P, but may be greater than the mask patterns P and may have a shape other than a tapered shape as long as they maintain uniformity of stress in the entire area of the mask 20. However, as the shapes of dummy patterns P and the mask patterns P are more identical to each other, the uniformity of stress levels may increase.

Meanwhile, the dummy patterns DP may be provided in a form in which a predetermined region is cut on the dummy portion DM of the mask 20. The dummy pattern DP may not be provided in plural, and may have a continuously connected shape without being regularly and repeatedly formed. For example, the dummy pattern DP may be provided in a form in which only the cell portions C of the mask 20 is left and the remaining portion is cut.

Referring to FIG. 13, a plurality of dummy cell regions DCR may be formed in the support 30. The dummy cell regions DCR may be arranged at predetermined intervals from the cell regions CR in the first direction (x-axis direction) and in the second direction (y-axis direction) that is perpendicular to the first direction. The predetermined interval between the dummy cell region DCR and the cell region CR may correspond to the predetermined interval between the cell regions CR. The first and second grid portions 33 and 35 may also be disposed between the dummy cell regions DCR and the cell regions CR. Since the dummy cell regions DCR serve the same function as the dummy cell portions DC described above, the description thereof will be replaced with the above description of the dummy cell portions DC.

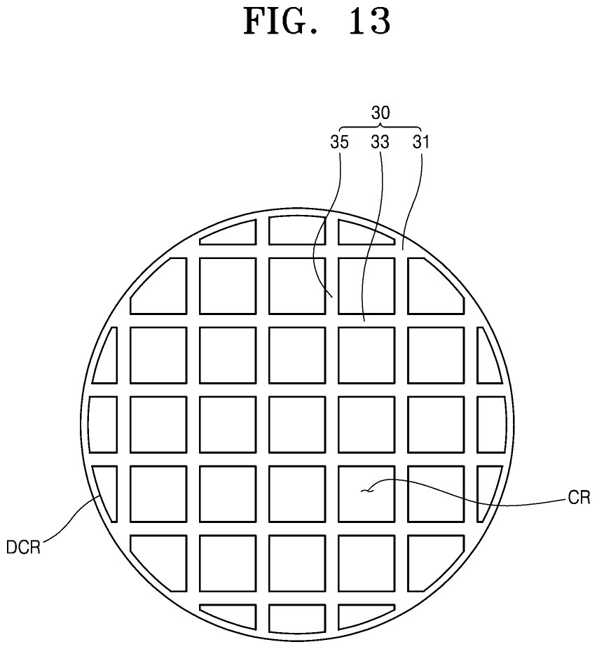

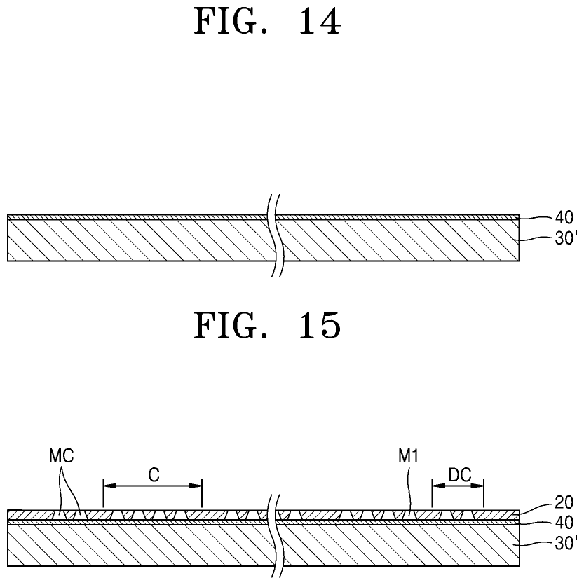

FIGS. 14 to 21 are schematic diagrams illustrating a producing process of a mask-support assembly 10-2 (or 10) according to a second embodiment of the present invention. Hereinafter, a producing process will be described assuming a mask-support assembly 10-2 including the dummy cell portions DC of FIG. 12 and the dummy cell regions DCR of FIG. 13. However, except for the dummy cell portions DC and the dummy cell regions DCR, the process may proceed as described with reference to FIGS. 5 to 11. In addition, in FIGS. 14 to 21, a detailed description of the same content as the description made above with reference to FIGS. 5 to 11 will not be reiterated.

Referring to FIG. 14, a support 30′ (or a conductive substrate 30′) is prepared.

Then, a connection portion 40 may be formed on one surface of the support 30′. The connection portion 40 may be formed by electroforming. Alternatively, when the material of the connection portion 40 is difficult to perform electroforming, the connection portion 40 may be formed using sputtering or brazing. The connection portion 40 may be formed of a material such as Ni, Cu, Au, Ag, Al, etc. that has high adhesion to the support 30′ when produced by electroforming. Alternatively, the connection portion 40 may be formed of a material such as Sn, In, Bi, Zn, Sb, Ge, Cd. etc. that has high adhesion to the support 30′ when produced by sputtering or brazing.

Since the connection portion 40 may serve to increase the adhesion between the support 30′ (or the conductive substrate 30′) and the mask 20 and to enable electroforming of the mask 20 on the connection portion 40, the connection portion 40 has a thinner thickness than that of the mask 20. Taking this into account, the thickness of the connection portion 40 does not exceed 20% of the thickness of the mask 20. In particular, if the connection portion 40 is too thin, it is difficult to achieve suitable adhesion between the support 30′ and the mask 20. If the connection portion 40 is is too thick, the quality of electroforming of the mask 20 may be affected or the connection portion remains too much after etching EC of the support 30′, which will be described below, so that the mask patterns P are covered. Thus, the thickness of the connection portion 40 is 0.1 μm to 1 μm.

Next, referring to FIG. 15, a patterned insulating portion M1 may be formed on one surface of the connection portion 40.

In addition to the insulating portion M1, a patterned insulating portion MC (or a dummy insulating portion MC) may be further formed on one surface of the support 30′. The insulating portion M1 may be formed on a region corresponding to the cell portion C and the insulating portion MC may be formed on a region corresponding to the dummy cell portion DC. The shape of the insulating portion MC may be the same as that of the insulating portion Ml. The insulating portion MC and the insulating portion M1 may be formed together in the same process.

Then, a mask 20 may be formed by performing electroforming on the connection portion Since the insulating portion M1 has the insulating properties, a plated film is not formed on a portion that corresponds to the insulating portion Ml, so that mask patterns P of the mask 20 may be formed. The mask patterns P may be formed on a region that corresponds to the cell portion C.

Since the insulating portion MC has the insulating properties, a plated film is not formed on a portion that corresponds to the insulating portion MC, so that a dummy pattern DP of the mask 20 may be formed. The dummy pattern DP may be formed on a region that corresponds to the dummy cell portion DC.

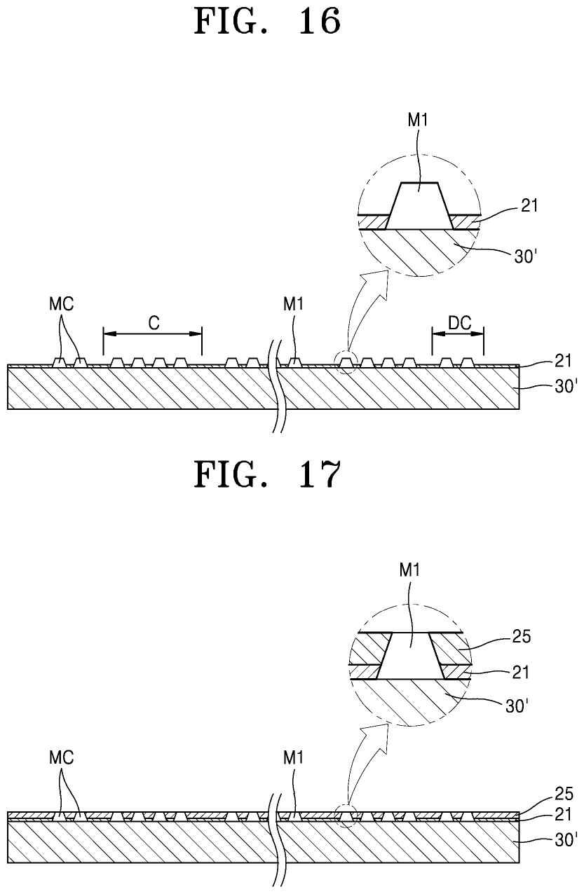

FIGS. 16 and 17 are schematic diagrams illustrating a forming process of a mask 20 of an embodiment different from the method of FIGS. 14 and 15.

Meanwhile, if the connection portion 40 of FIG. 14 is made of a material capable of electroforming, it may be replaced with a first mask layer 21 as shown in FIGS. 16 and 17.

First, referring to FIG. 16, patterned insulating portions M1 and MC may be formed on one surface of a support 30′ (or a conductive substrate 30′). Thereafter, the first mask layer 21 may be formed by performing electroforming on the support 30′. Since the insulating portions M1 and MC have insulating properties, a plated film is not formed on portions that corresponds to the insulating portions M1 and MC, so that mask patterns P/dummy patterns DP of the first mask layer 21 may be formed. The mask patterns P (or the insulating portion M1) may be formed on a region that corresponds to the cell portion C.

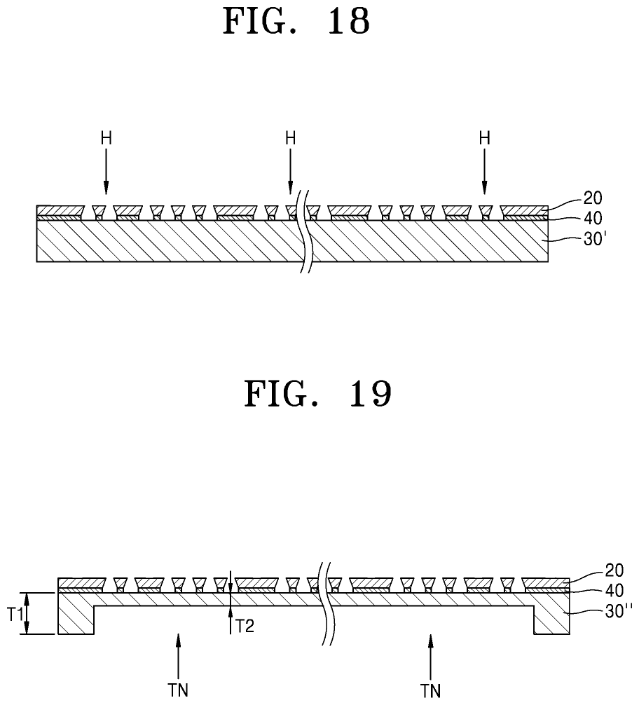

The first mask layer 21 may include any one material of Ni, Cu, Au, Ag, Al, Co, Ti, Cr, W, or Mo that has high adhesion to the support 30′ when produced by electroforming. Alternatively, the first mask layer 21 may be formed of a metal material capable of forming silicide with the support 30′. As will be described below, in the process of heat treatment H (see FIG. 18) of the mask 20 and the support 30′, it is necessary to ensure that the mask 20 strongly adheres to the support 30′ so as not to be peeled off. Therefore, the first mask layer 21 having stronger adhesion to the support 30′ than the material of a second mask layer 25 may be first formed on the support 30′. The first mask layer 21 may play the same role as the connection portion 40 of FIG. 14.

However, since the first mask layer 21 has high adhesion to the support 30′, but may have a high coefficient of thermal expansion and low strength, the first mask layer 21 needs to be formed such that the proportion of the thickness of the first mask layer 21 is smaller than that of the second mask layer 25 in the mask 20. Taking this into account, the first mask layer 21 may be formed to to a thickness of 0.01% to 5% of the thickness of the mask 20, or a thickness of 0.03% to 2%.

Then, referring to FIG. 17, the second mask layer 25 may be formed by performing electroforming on the first mask layer 21. The second mask layer 25 may be made of a different material from that of the first mask layer 21. Since the first mask layer 21 is conductive and insulating portions M1 and MC have insulating properties, the second mask layer 25 may be formed on the first mask layer 21 and include mask patterns P/dummy patterns DP. The second mask layer 25 may be made of a material, such as Invar, Super Invar, or the like, which has high adhesion to the first mask layer 21, a low coefficient of thermal expansion, and high strength, when produced by electroforming. In addition, the second mask layer 25 may be formed to be thicker than the first mask layer 21 so that the second mask layer 25 is mainly responsible for a coefficient of thermal expansion and strength in the mask 20. Taking this into account, the second mask layer 25 may be formed to a thickness of 95% to 99.99% of the thickness of the mask 20, or a thickness of 98% to 99.97%. For example, when the total thickness of the mask 20 is approximately 2 to 15 μm, the thickness of the first mask layer 21 may be formed to be approximately 10 to 300 nm.

The mask 20 may be formed by sequentially stacking the first mask layer 21 and the second mask layer 25.

In addition, the thicknesses of the first and second mask layers 21 and 25 may be controlled such that the mask 20 has a coefficient of thermal expansion similar to that of the silicon material of the support 30′. As the first and second mask layers 21 and 25 have different coefficients of thermal expansion, the coefficient of thermal expansion of the mask 20 may vary according to the thickness ratio of the first and second mask layers 21 and 25. For example, as the proportion of thickness of the first mask layer 21 having a relatively high coefficient of thermal expansion to total thickness of the mask 20 increases, the coefficient of thermal expansion of the entire mask 20 may increase. On the contrary, as the proportion of thickness of the second mask layer 25 having a relatively low coefficient of thermal expansion to total thickness of the mask 20 increases, the coefficient of thermal expansion of the entire mask 20 may decrease. The proportions of thickness of the first and second mask layers 21 and 25 may be controlled by adjusting the duration of electroforming.

Hereinafter, subsequent processes will be described assuming an example in which a mask 20 formed by electroforming after forming the connection portion 40 of FIGS. 14 and 15. However, the following processes may be equally applied to the example of forming the mask 20 by sequentially stacking the first and second mask layers 21 and 25 on the support 30′ of FIGS. 16 and 17.

Then, referring to FIG. 18, heat treatment H may be performed on the mask 20 and the support 30′. The heat treatment H may also be performed on the connection portion 40. The heat treatment H may be performed at a temperature of 300° C. to 800° C., or at a temperature of approximately 200° C. to 400° C., which is a low temperature range. The heat treatment may be performed with less heat by further applying a predetermined pressure during the heat treatment H process. A process of removing the insulating portions M1 and MC may be performed prior to and/or after the heat treatment H.

In addition to the effects of the heat treatment H described above with reference to FIG. 7, the present invention has an effect of bonding the mask 20 to the support 30′ due to the heat treatment H. In one example, in the process of heat treatment H, the connection portion 40 between the mask 20 and the support 30′, which is melted into liquid phase by heat treatment and then solidified again, may mediate adhesion between the mask 20 and the support 30′. The connection portion 40 may act as an adhesion layer or a glue layer. In another example, the connection may be performed by varying the interfacial state of the mask 20, the support 30′, and the connection portion 40 in such a manner that metal components of the connection portion 40 diffuse into the mask 20 and the support 30′, or conversely, the components of the mask 20 and the support 30′ diffuse into the connection portion 40 or the components of the mask 20, the support 30′, and the connection portion 40 diffuse mutually into each other.

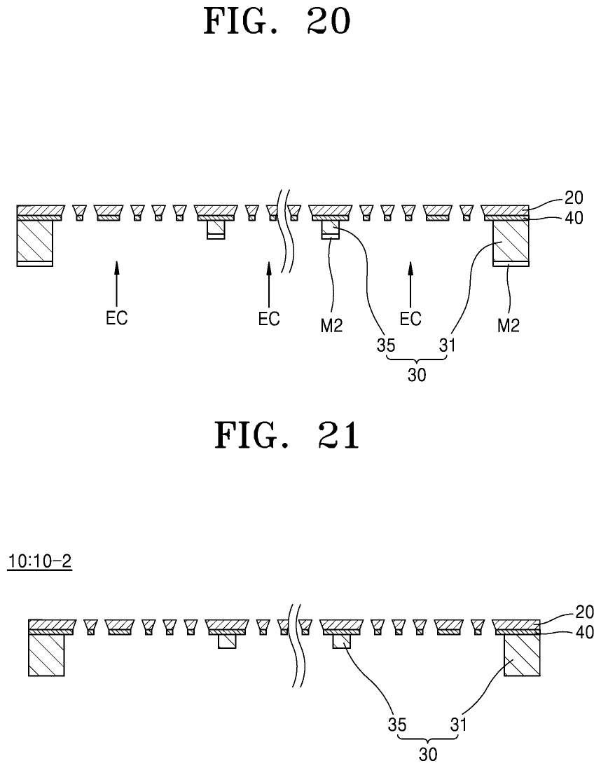

Then, referring to FIGS. 19 and 20, the support 30′ (or a conductive substrate 30′) may be subjected to a thickness reduction process TN and the support 30′ may be subjected to etching EC. The description made above with reference to FIGS. 8 and 9 may be applied without change to this process.

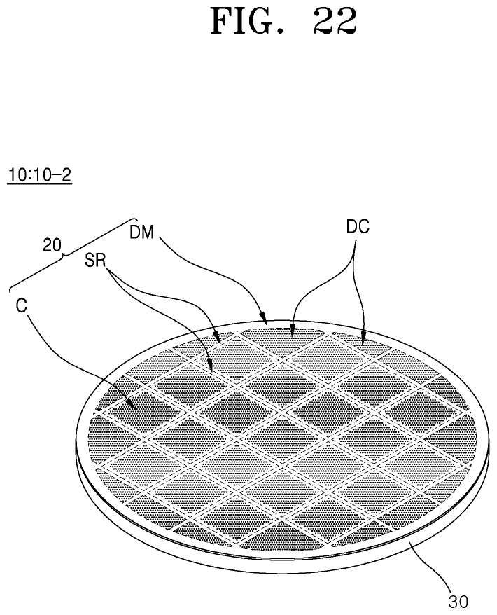

FIG. 22 is a schematic diagram illustrating a mask-support assembly 10-2 (or 10) according to another embodiment of the present invention.

Referring to FIGS. 21 and 22, the mask-support assembly 10-2 may be produced by removing the insulating portion M2 and performing a subsequent process, such as cleaning or the like. A support 30 may include an edge portion 31 and first and second grid portions 33 and 35, and a mask 20 may be connected onto the support 30 by interposing a connection portion 40 between them. Although it is illustrated that edges of the mask 20 and the support 30 match with each other, the edge of the support 30 may be formed larger than the edge of the mask 20, or vice versa.

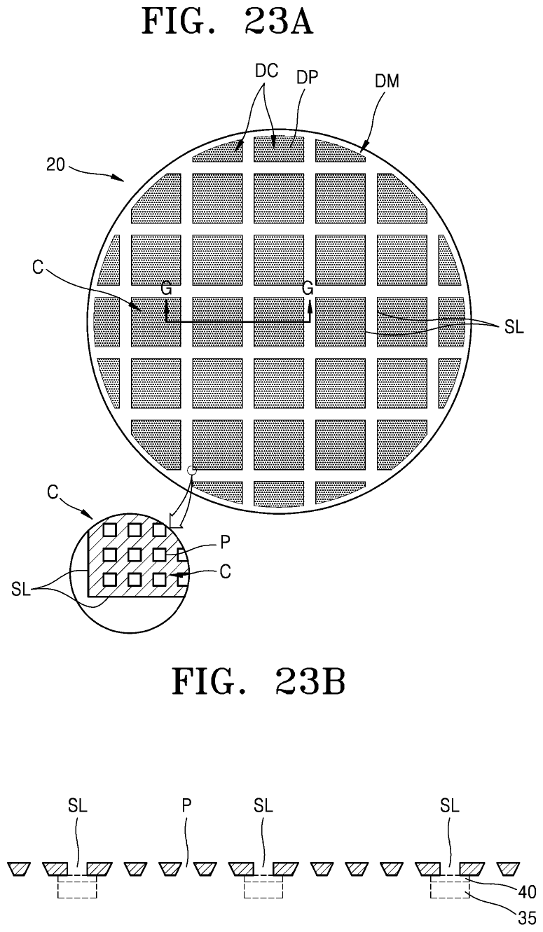

FIGS. 23A-23B illustrate a schematic plan view and a schematic side cross-sectional view taken along line G-G′ showing a mask on which slit lines SL are formed according to an embodiment of the present invention.

Referring to FIGS. 23A-23B, a mask 20 may include a plurality of cell portions C that include a plurality of mask patterns P. In addition, slit lines SL may be formed between each cell portion C. The cell portions C may be spaced apart from each other by the slit lines SL. In addition, one side of each of neighboring cell portions C in each pair may be supported on the same first and second grid portions 33 and 35 and the connection portion 40. Referring to (b) of FIG. 23B, it can be shown that the right side and the left side of two neighboring cell portions C are supported on a second grid portion 35 and the connection portion 40 represented by dotted lines.

Unlike the mask 20 in which the cell portions C are connected to each other through the separation portions SR as shown in FIG. 2, the cell portions C of the mask 20 of FIGS. 23A-23B may be spaced apart from each other by the slit lines SL. As the cell portions C exist independently of each other by the slit lines SL without being connected to each other, residual stress exists only in each cell portion C and is prevented from affecting other cell portions C.

FIG. 24 is a schematic diagram showing an OLED pixel deposition apparatus 1000 to which a mask-support assembly 10 according to one embodiment of the present invention is applied.

Referring to FIG. 24, the OLED pixel deposition apparatus 1000 includes a magnet plate 1300 in which a magnet 1310 is accommodated and a cooling water line 1350 is disposed, and a deposition source supply 1500 configured to supply an organic material source 1600 from a lower portion of the magnet plate 1300.

A target substrate 1900, such as glass, on which the organic material source 1600 is to be deposited may be interposed between the magnet plate 1300 and the deposition source supply 1500. The mask-support assembly 10 for enabling deposition of the organic material source 1600 per pixel may be positioned in contact with or very close to the target substrate 1900. The magnet 1310 may generate a magnetic field and the mask-support assembly 10 is brought in contact with or very close to the target substrate 1900 due to the attraction by the magnetic field.

The deposition source supply 1500 may supply the organic material source 1600 while horizontally reciprocating, and the organic material source 1600 supplied from the deposition source supply 1500 may pass through mask patterns P formed on the mask-support assembly 10 and be deposited on a surface of the target substrate 1900. The organic material source 1600 deposited through the mask patterns of the mask-support assembly 10 may serve as pixels 1700 of an OLED.

Since the mask pattern P is formed to have sloped sides (formed in a tapered shape), non-uniform deposition of the OLED pixels 1700 due to shadow effect may be prevented by the organic material source 1600 passing through the mask patterns P along the sloped direction.

As described above, a support 30, which is a frame, is formed by processing and connecting the mask 20 and a support 30′ in a state in which a separate physical tension is not applied to the mask 20 after forming the mask 20 on the support 30′ (or a conductive substrate 30′) through electroforming. Thus, there is no risk of misalignment of the mask 20. Accordingly, the mask 20 is clearly aligned so that stability of pixel deposition can be improved and at the same time an ultra-high resolution of 2000 PPI or higher can be realized.

According to the present invention with the above-described configuration, it is possible to realize ultra-high-resolution pixels of a microdisplay.

In addition, according to the present invention, it is possible to improve stability of pixel deposition by allowing a mask to be clearly aligned.

In addition, according to the present invention, it is possible to allow all parts of a mask to have uniform stress levels.

However, the scope of the present invention is not limited by the above effects.

While the present invention has been particularly shown and described with reference to embodiments thereof, it will be understood by one of ordinary skill in the art that various changes in form and details may be made therein without departing from the scope of the present invention as defined by the following claims.

### REFERENCE NUMERALS

10: MASK-SUPPORT ASSEMBLY
20: MASK
21, 25: FIRST AND SECOND MASK LAYERS
30 ′ CONDUCTIVE SUBSTRATE, SUPPORT
30: SUPPORT
31: EDGE PORTION
33, 35: FIRST AND SECOND GRID PORTIONS
40: CONNECTION PORTION
1000: OLED PIXEL DEPOSITION APPARATUS
C, SR, DM: CELL PORTION, SEPARATION PORTION, DUMMY PORTION
P: MASK PATTERN
SL: SLIT LINE

What is claimed is:

1. A mask-support assembly which is used in a process of forming organic light-emitting diode (OLED) pixels on a semiconductor wafer, the mask-support assembly comprising:
a support comprising an edge portion and a grid portion; and
a mask connected onto the support and comprising a plurality of cell portions,
wherein the plurality of cell portions have a plurality of mask patterns, respectively.

2. The mask-support assembly of claim 1,
wherein a thickness of the grid portion is thinner than a thickness of the edge portion.

3. The mask-support assembly of claim 1,
wherein the support and the mask have a circular shape, and
wherein the grid portion comprises:
is a plurality of first grid portions extending in a first direction and having opposite ends connected to the edge portion; and
a plurality of second grid portions extending in a second direction different from the first direction, intersecting the first grid portions, and having opposite ends connected to the edge portion.

4. The mask-support assembly of claim 3,
wherein the mask further comprises:
a dummy portion connected onto the edge portion; and
separation portions positioned closer to a central part of the mask than the dummy portion and disposed in spaces between two adjacent cell portions of the plurality of cell portions, and
wherein the separation portions are supported on the grid portion, and
wherein the plurality of cell portions are disposed at the central part of the mask.

5. The mask-support assembly of claim 3, wherein the support is formed from a silicon wafer and the mask is formed on the silicon wafer by electroforming.

6. The mask-support assembly of claim 5, wherein a connection potion including Ni and Si or a connection portion including Fe, Ni, and Si is interposed between the support and the mask.

7. The mask-support assembly of claim 5, further comprising:
a connection portion interposed between the support and the mask,
wherein the connection portion includes at least one of Ni, Cu, Au, Ag, Al, Sn, In, Bi, Zn, Sb, Ge, and Cd.

8. The mask-support assembly of claim 1,
wherein the mask is formed of at least one of Invar, Super Invar, nickel (Ni), cobalt (Co), titanium (Ti), chromium (Cr), tungsten (W), and molybdenum (Mo).

9. The mask-support assembly of claim 1, wherein:
the mask comprises a first mask layer and a second layer, the second mask layer being formed of a material different from a material of the first mask layer,
the first mask layer is formed of a material including at least one of Ni, Cu, Au, Ag, Al, Co, Ti, Cr, W, and Mo,
the second mask layer is formed of Invar or Super Invar, and
the first mask layer disposed between the support and the second mask layer and connecting the support to the second mask layer.

10. The mask-support assembly of claim 5,
wherein a longitudinal direction of the first grid portions or a longitudinal direction of the second grid portions is different from a crystal orientation of a (100) plane or (111) plane of the silicon wafer.

11. The mask-support assembly of claim 3,
wherein the mask further comprises:
is a dummy portion connected on the edge portion; and
slit lines are formed in spaces between two adjacent cell portions of the plurality of cell portions, and
wherein the plurality of cell portions are positioned closer to a central part of the mask than the dummy portion.

12. The mask-support assembly of claim 5,
wherein the edge portion and the grid portion include tapered sides.

13. The mask-support assembly of claim 5,
wherein a surface resistance of the support is selected from a range of 5×10⁻⁴ ohm·cm to 1×10⁻² ohm·cm.

14. The mask-support assembly of claim 4,
wherein the dummy portion comprises a plurality of dummy cell portions that include a plurality of dummy patterns passing through the dummy portion or extending into the dummy portion to a predetermined depth.

15. A producing method of a mask-support assembly which is used in a process of forming organic light-emitting diode (OLED) pixels on a semiconductor wafer, the producing method comprising the steps of:
(a) preparing a support which includes a first surface and a second surface opposite to the first surface and is a conductive substrate;
(b) forming a mask on the first surface by electroforming;
(c) performing heat treatment on the support and the mask; and
(d) forming an edge portion and a grid portion by etching the support on the second surface of the support.

16. The producing method of claim 15, further comprising:
(a2) forming, between steps (a) and (b), a connection portion including at least one of Ni, Cu, Au, Ag, Al, Sn, In, Bi, Zn, Sb, Ge, and Cd,
wherein in step (b), the mask is formed on the connection portion by electroplating.

17. The producing method of claim 15, wherein, after the heat treatment in step (c), the mask and the support are connected to each other by interposing a connection portion including Ni and Si or a connection portion including Fe, Ni, and Si.

18. The producing method of claim 15,
wherein the heat treatment in step (c) is performed at a temperature selected from a range of 200° C. to 800° C.

19. The producing method of claim 15, further comprising:
(c2) reducing, between steps (c) and (d), a thickness of at least a region where the grid portion is to be formed on the second surface of the support portion.

20. A mask-support assembly which is used in a process of forming OLED pixels on a semiconductor wafer, the mask-support assembly comprising:
a support having a circular shape, wherein the support comprises:
an edge portion;
a plurality of first grid portions extending in a first direction and having opposite ends connected to the edge portion; and
a plurality of second grid portions extending in a second direction different from the first direction, intersecting the first grid portions, and having opposite ends connected to the edge portion;
a mask having a circular shape, wherein the mask is connected onto the support, and comprises a plurality of cell portions having a plurality of mask patters, respectively; and
a connection portion connecting the support to the mask,
wherein the support is formed from a silicon wafer,
wherein the mask is formed on the silicon wafer by electroforming,
wherein the connection portion comprises any one of the following (1) to (3):
(1) Ni and Si;
(2) Fe, Ni, and Si; and
(3) at least one of Ni, Cu, Au, Ag, Al, Sn, In, Bi, Zn, Sb, Ge, and Cd, and
wherein the mask is formed of at least one of Invar, Super Invar, nickel (Ni), cobalt (Co), titanium (Ti), chromium (Cr), tungsten (W), and molybdenum (Mo).
